(19) United States
(12) Patent Application Publication
(10) Pub. No.: US 2015/0295581 A1
(43) Pub. Date: Oct. 15, 2015

(54) Distributed Cooperative Control for Microgrid Resynchronization and Reconnection

(71) Applicant: NEC Laboratories America, Inc., Princeton, NJ (US)

(72) Inventors: Di Shi, Fremont, CA (US); Ratnesh Sharma, San Jose, CA (US)

(21) Appl. No.: 14/678,053

(22) Filed: Apr. 3, 2015

Related U.S. Application Data
(60) Provisional application No. 61/978,052, filed on Apr. 10, 2014.

(51) Int. Cl. H03L 5/02; G05B 11/42

(52) U.S. Cl. CPC H03L 5/02; G05B 11/42

(57) ABSTRACT

Systems and methods are disclosed for distributed cooperative control strategy between a microgrid and a main grid by providing distributed synchronization and reconnection of the distributed generators with sparse communication channels, wherein each distributed generator only receives information from neighboring generators; receiving a voltage phase angle difference and a voltage magnitude difference by a proportional integration (PI) controller to adjust the output of the distributed generator at a leader node, wherein each distributed generator shares an output frequency and a voltage with neighbors; achieving a consensus behavior between all the distributed generators; sharing power generation among the distributed generators; and synchronizing the microgrid with the main grid for a seamless reconnection after islanding.

This application claims priority to Provisional Application Ser. No. 61/978,052 filed on Apr. 10, 2014, the content of which is incorporated by reference.

### BACKGROUND

The present invention relates to microgrid resynchronization and reconnection.

Microgrids, which are localized grids that can disconnect from the main grid to operate autonomously and help mitigate grid disturbances to strengthen grid resilience, can play an important role in transforming our electric grid. Microgrids can strengthen grid resilience and help mitigate grid disturbances because they are able to continue operating while the main grid is down, and they can function as a grid resource for faster system response and recovery.

A microgrid typically integrates multiple distributed generators and load within a localized distribution network. A microgrid can work under two modes: the grid-tied mode and the islanded mode. In grid-tied mode, a microgrid absorbs power from or injects power into the main grid, following the voltage and frequency reference provided by the main grid. In islanded mode, a microgrid is disconnected from the main grid and operates in a similar way as a physical island, balancing its own power generation and load. After islanding occurs, microgrid will either accelerate or decelerate even due to small power imbalance and will lose synchronism with the main grid. When the factors that trigger islanding disappear, the main grid is restored and microgrid needs to be connected back to the utility grid. Asynchronism can be a big problem for microgrid reconnection. The voltage difference across the microgrid static switch (or circuit breaker) will lead to large inrush current and fluctuation, which will shorten the life of the equipment and may even damage the distributed generators. To achieve a smooth and successful reconnection, microgrid must be synchronized to the main grid when operating in islanded mode before reconnection occurs. The voltage magnitude difference, phase angle difference, and frequency difference at point of common coupling (PCC) on both sides of the static switch/circuit breaker must strictly follow the requirements set forced by the IEEE 1547™ standard. The resynchronization and reconnection problem needs to be solved in order to fulfill the benefits of the microgrid concept.

One current control scheme minimizes the frequency mismatch between microgrid and the main grid by controlling the output of the diesel generator. Measurements from two Phasor measurement units are used to evaluate the control actions. But having the same frequency does not guarantee the voltage phase angles across the static switch are the same, which is a problem of this method. The intentional use of frequency error in the control loop makes the reconnection process long and reclosing time indefinite, which weakens the practicability of the method.

### SUMMARY

In one aspect, systems and methods are disclosed for distributed cooperative control strategy between a microgrid and a main grid by providing distributed synchronization control to the distributed generators with sparse communication channels, wherein each distributed generator only receives information from neighboring generators; receiving a voltage phase angle difference and a voltage magnitude difference by a proportional integration (PI) controller to adjust the output of the distributed generator at a leader node, wherein each distributed generator shares an output frequency and a voltage with neighbors; achieving a consensus behavior between all the distributed generators; sharing power generation among the distributed generators; and synchronizing the microgrid with the main grid for a seamless reconnection after islanding.

In another aspect, a distributed cooperative control strategy can synchronize a microgrid with the main grid so that seamless reconnection can be achieved after islanding. Synchronization is achieved through distributed cooperative control of multiple distributed generators by adjusting their voltage and frequency reference so that the voltage phase angle difference and voltage magnitude difference across the circuit breaker/static switch are eliminated.

A distributed cooperative consensus control strategy is used to solve the resynchronization and reconnection problem in a distributed way. The method uses sparse communication channels and each distributed generator only needs to get information from its neighboring generators. Therefore minimum communication is achieved. The voltage phase angle difference and voltage magnitude difference are input into a PI controller to adjust the output of the distributed generator at the leader node. Each distributed generator shares its output frequency and voltage with its neighbors and finally consensus behavior is achieved between all the distributed generators.

Advantages of the system may include one or more of the following. The system can measure voltage magnitudes and phase angles at PCC on both sides of the static switch/circuit breaker. A synchronization controller calculates the adjustments that need to be made to the voltage and frequency setpoints of the microgrid. Adjustment signals are sent to distributed generators at leading node(s). The rest distributed generators will follow the generator(s) at leading node(s) through sparse communication and designed consensus protocol. This method is applicable to microgrid with multiple distributed generators, all of which actively regulate their output voltages and frequencies. With multiple generators in the microgrid, cooperation between generators is properly handled.

### BRIEF DESCRIPTION OF THE DRAWINGS

FIGS. 1A, 1B and 1C show exemplary systems with distributed control, centralized control and decentralized control.

FIG. 2 shows an exemplary microgrid with distributed cooperative control.

FIG. 3 shows an exemplary graph and its spanning tree with node 1 as the root.

FIG. 4 shows an exemplary control block diagram for phase angle and frequency synchronization.

FIG. 5 shows an exemplary adjustment made to the phase angle difference.

FIG. 6 shows an exemplary control block diagram for voltage magnitude setpoint adjustment.

FIG. 7 shows an exemplary voltage control loop for an i^{th} distributed generator.

FIG. 8 shows an exemplary frequency control loop for the i^{th} DG.

### DESCRIPTION

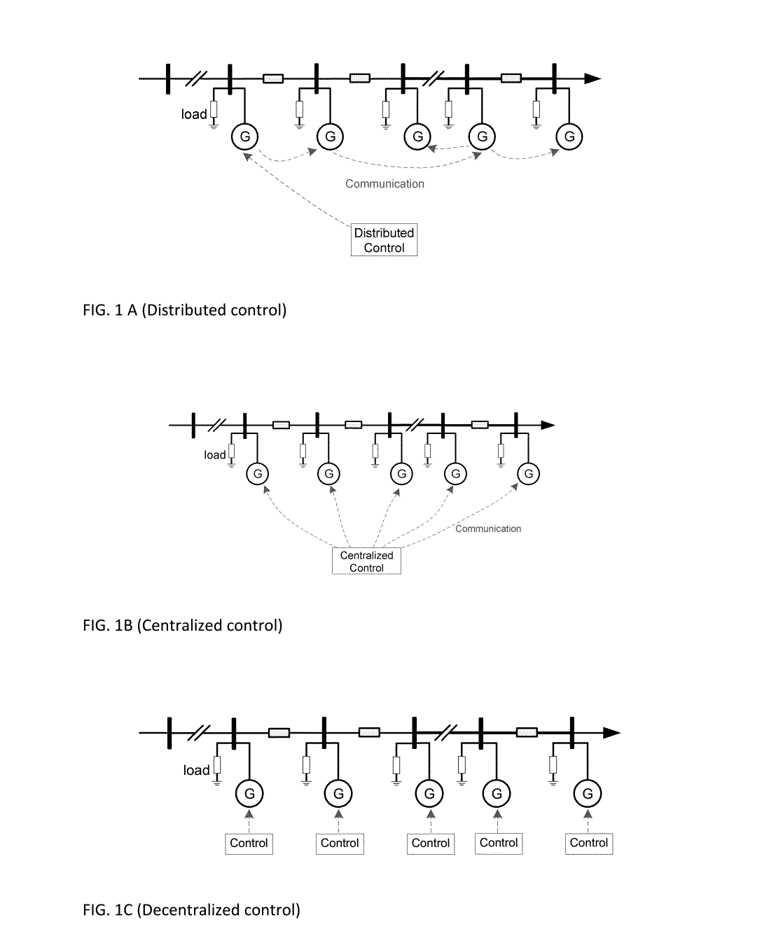

FIGS. 1A, 1B and 1C show exemplary systems with distributed control, centralized control and decentralized control, respectively. The system provides a distributed cooperative control framework to synchronize an islanded microgrid with the main grid for microgrid resynchronization and reconnection purpose. The centralized control is what is being used in modern power systems. Control decision is made at the central controller and then sent to each individual generator. Centralized control requires much more and longer communication infrastructure. The decentralized control is presently being used for microgrid. Each generator is controlled individually without communicating with each other. Decentralized control cannot be used for microgrid synchronization and reconnection with multiple distributed generators working as masters.

In the instant distributed control, control decision is made at the controller and sent to generator(s) at the leading node(s). The leading node(s) will share its own control action to its neighbors. Therefore, consensus is achieved and all generators in the system will follow the generator(s) at the leading node(s).

In an islanded microgrid, all distributed generator should work under droop control so that power can be properly shared among them when load changes. The voltage droop and frequency droop are defined by the following set of equations:

wᵢ=w*ᵢ−k_{Pi}·Pᵢ (1)

Vᵢ=V*ᵢ−k_{Qi}·Qᵢ (2)

where wᵢ and Vᵢ are the output frequency and terminal voltage of the i th DG, w*ᵢ and V*ᵢ are the frequency and voltage reference of the i th DG, k_{Pi} and k_{Qi} are the corresponding droop coefficients for real and reactive power.

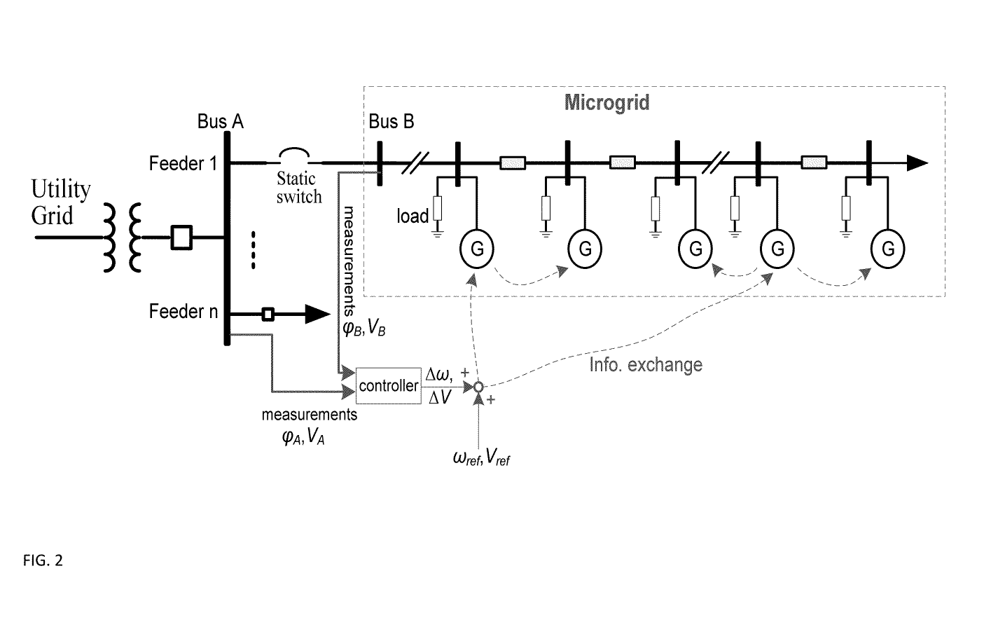

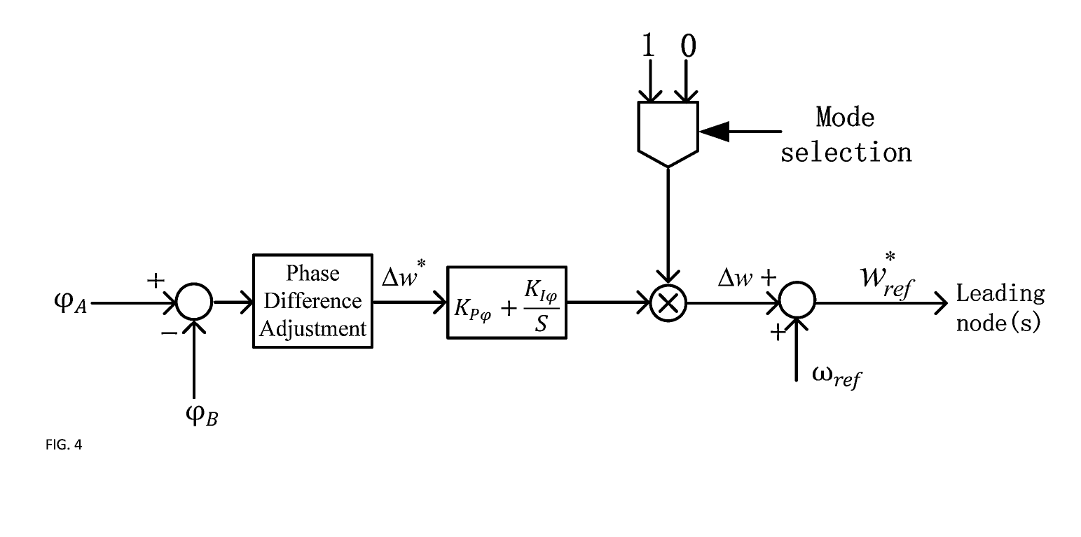

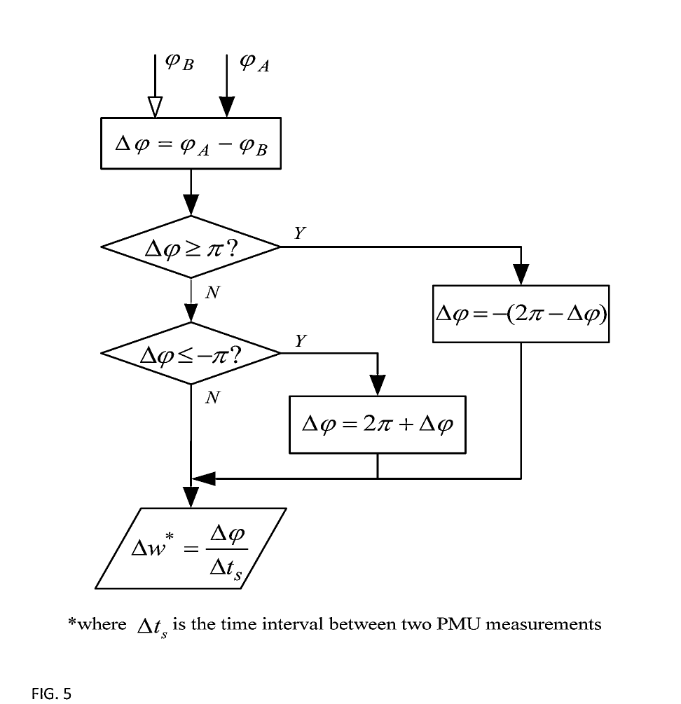

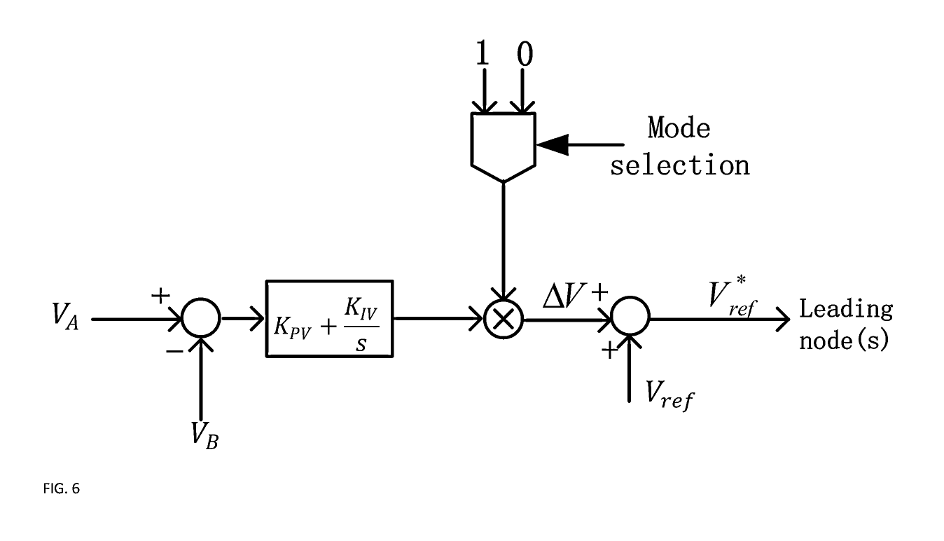

Measurements at Both Sides of Static Switch/Circuit Breaker are discussed next. FIG. 2 shows the microgrid with a distributed cooperative control. In order to synchronize microgrid with the main grid for reconnection, the voltage magnitude and phase angle on the microgrid side (at bus B) need to be measured and compared with those on the main grid side (at bus A). FIG. 2 shows the phase angles (φ_{A}, φ_{B}) and voltage magnitudes (V_{A}, V_{B}) measured at buses A and B across the static switch/circuit breaker are input into the controller for synchronization control. FIG. 4 is the frequency control loop inside the controller shown in FIG. 2, and FIG. 5 is the phase difference adjustment as shown in FIG. 4. FIG. 6 is the voltage control loop which resides in the controller of FIG. 2. Voltage phase angles and magnitudes at buses on both sides of the static switch (recloser/circuit breaker) are measured and input into the controller. The controller calculates the adjustments to the frequency and voltage magnitude setpoints that should be made to the distributed generators. The controller sends the adjustment signals to one (or some) generator(s) at the so-called leading node(s). Based on the designed consensus protocol, leading node(s) share its information with neighboring nodes. Once a node receives control information, it shares its own information with its downstream neighboring node. Finally, all generators follow the behavior(s) of the generator(s) at the leading node(s). Therefore, voltage magnitude, phase angle and frequency on both sides of the static switch/circuit breaker will be the same before reconnection occurs.

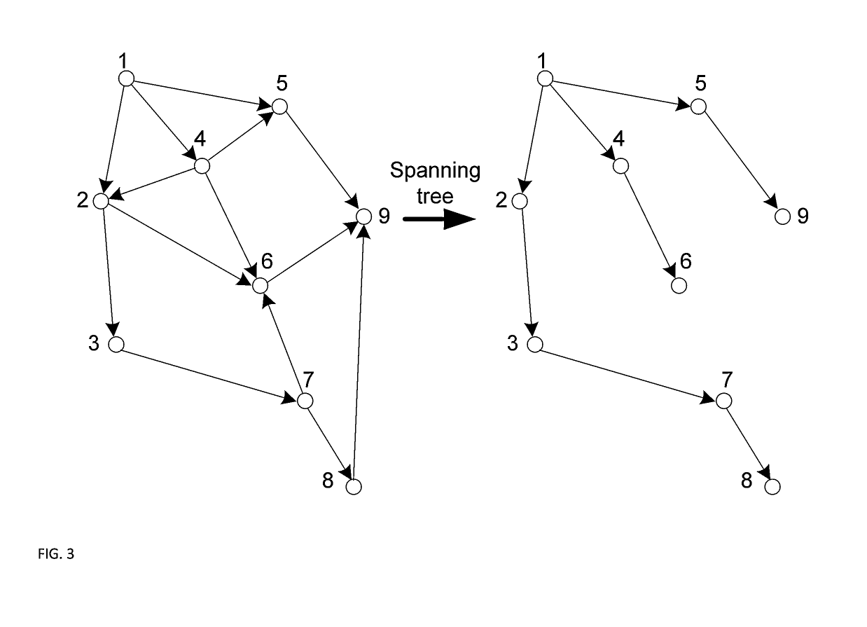

Sparse Communication and Flexible Topology are detailed next. The distributed control framework in this system requires only information exchange between distributed generator and its neighboring units. The topology of the communication network is localized and can be very flexible. The communication system can be modeled by graph, which is shown in FIG. 3 and discussed next.

Consider a directed graph G=(V, E) with V={v₁, v₂, . . . , v_{N}} being a set of N nodes or vertices and E a set of edges. Each distributed generator can be considered as a node. Each edge (vᵢ, vⱼ) represents that information can flow from node vᵢ to node vⱼ. Define the neighbors of node i as Nᵢ={vⱼ:(vⱼ, vᵢ)εE}. Each edge (vᵢ, vⱼ)εE is associated with a weight aⱼᵢ. A graph can be represented by an adjacency matrix A=[aᵢⱼ] with weights aᵢⱼ>0 if (vⱼ, vᵢ)εE and aᵢⱼ=0 otherwise. We assume the graph is simple and there is no self-loops, so aᵢᵢ=0∀i. For edge (vᵢ, vⱼ), vᵢ is called the tail and vⱼ is the head. The in-degree of a node vᵢ is the number of edges that have vᵢ as a head. The out-degree of a node vᵢ is the number of node that have vias a tail. A directed tree is a connected digraph where every node except one, called the root, has in-degree equal to one. A spanning tree of a digraph is a directed tree formed by graph edges that connect all the nodes of a graph.

FIG. 3 shows a graph and a spanning tree of the graph with node 1 as the root. Compared to the centralized control in which communication between the central controller and each distributed generator is needed, this system requires only sparse communication between each distributed generator and its neighbors. The topology of the communication network is flexible in the sense that the distributed control strategy will stay effective as long as there exists a spanning tree in the communication graph after adding or removing one or several distributed generators.

An important characteristic of the microgrid is its plug-and-play feature. When a new distributed generator is added into the microgrid, no additional changes need to be made to the communication network and control strategy except that this new unit can communicate with existing generators that are close to it. The basic idea of the synchronization control strategy is to adjust the voltage magnitude and frequency setpoints for each distributed generator in a distributed manner so that the voltage at bus B (PCC on microgrid side) closely follows bus A (PCC on main grid side). The voltage magnitude and frequency adjustments are achieved through two independent control loops.

FIG. 4 shows a control block diagram for phase angle setpoint adjustment. Phase angle at bus B should closely follow the phase at bus A. This is achieved through the following control loop shown in FIG. 4. The mode selection unit enables/disables the synchronization control. When the mode is selected to be 1, the synchronization control is activated; otherwise it is deactivated. Phase angles from buses A and B are subtracted, and passed through a PI controller to determine K_{Pφ}+K_{Iφ}/s, where K_{Pφ} is the proportional gain of the PI controller, and K_{Iφ} is the integral gain of the PI controller. The output is passed through a mode selection switch, and if the mode for 1 is selected, the change in w is added to the reference frequency w_{ref} to generate w*_{ref}.

Phase Angle Difference Adjustments can be done. The adjustment employed is shown in FIG. 5 where adjustments are made to the phase angle difference. The phase angle difference (φ_{A}-φ_{B} or Δφ) needs to be adjusted before it is fed into the PI controller. This is mainly due to the periodic feature of the sine wave. In this system, the phase angle difference is limited within the range between −180 degrees to 180 degrees.

FIG. 6 shows a control block diagram for voltage magnitude setpoint adjustment. Phase angle and frequency synchronization of the microgrid is achieved by adjusting the frequency setpoint of each distributed generator in a distributed manner. The mode selection unit enables/disables the synchronization control. When the mode is selected to be 1, the synchronization control is activated; otherwise it is deactivated. In this figure, voltages from buses A and B are subtracted, and pass through a PI controller to determine K_{PV}+K_{IV}/s, where K_{PV} is the proportional gain of the PI controller, and K_{IV} is the integral gain of the PI controller. The output is passed through a mode selection switch, and if the mode for 1 is selected, the change in V is added to the reference voltage V_{ref} to generate V*_{ref}.

Next, Distributed Cooperative Voltage Control is detailed. A consensus control technique is used in this system to control each individual distributed generator so that they will follow the voltage reference signal sent to the leading node(s) by the synchronization controller. With the time step of the voltage control, the fast dynamics within each distributed generator are ignored. In particular, each distributed generator in the microgrid is modeled as a first-order dynamic system, which is characterized by:

\dot{x}ᵢ=uᵢ (3)

where \dot{x}ᵢ is the state of the i th distributed generator and uᵢ is the control input for it which is based on information received from neighboring units defined in the communication digraph. Define B as the set of the leading nodes in the communication digraph. The voltage control problem is transformed into a consensus control problem, the objective of which is to find/design uᵢ such that all distributed generator states will converge to the external control signal sent to the leading nodes. A necessary and efficient condition for the distributed generators' states to converge to the external reference signal is that the communication digraph has a spanning tree with B as leading node(s).

Reactive Power Sharing can occur among Distributed Generators. The objective of the voltage synchronization control problem is to select the state variable xᵢ and control input uᵥᵢ for the dynamic system described by:

$${\dot{x}}_{i} = {u}_{i} = {\sum }_{j ∈ {N}_{i}} {a}_{ij} ( {x}_{j} - {x}_{i} ) + {b}_{i} ( {V}_{ref}^{*} - {x}_{i } ) \qquad ( 4 )$$

where bᵢ=1 if iεB and bᵢ=0 otherwise.

For each distributed generator, the voltage droop control function has been defined in equation (2). Take derivative on both sides of this equation, the following can be obtained:

\dot{V}ᵢ=\dot{V}* ᵢ−k_{Qi}·\dot{Q}ᵢ (5)

When the voltage setpoint of a distributed generator is adjusted, the generator adjusts its reactive power output so that system voltage follows the new setpoint. In general, the change in each distributed generator's reactive power output is preferably proportional to its maximum reactive power generation capability, that is:

$$\frac{{Q}_{1}}{{Q}_{1 \_ max}} = \frac{{Q}_{2}}{{Q}_{2 \_ max}} = … = \frac{{Q}_{i}}{{Q}_{i\_max}} \qquad ( 6 )$$

where Qᵢ_{_{—}}ₘₐₓ is the maximum reactive power generation capability for generator i As the common practice, droop coefficient (k_{Qi}) is selected based on each unit's maximum reactive power generation capability.

k_{Q1}Q₁=k_{Q2}Q₂= . . . =k_{Qi}Qᵢ (7)

Voltage Consensus Control Design is discussed next. Based on equation (4), select the state variable to be the voltage setpoint for each distributed generator's droop control:

\dot{x}ᵢ=\dot{V}*ᵢ=\dot{V}ᵢ+k_{Qi}·\dot{Q}ᵢ=u_{Vi} (8)

Therefore, the voltage synchronization problem can be transformed into a synchronization problem for the following linear first-order multi-agent system:

$$\{ \begin{matrix}{\dot{V}}_{1} + {k}_{Q 1} \cdot {\dot{Q}}_{1} = {u}_{V 1} \\ {\dot{V}}_{2} + {k}_{Q 2} \cdot {\dot{Q}}_{2} = {u}_{V 2} \\ ⋮ \\ {\dot{V}}_{i} \cdot {k}_{Qi} \cdot {\dot{Q}}_{i} = {u}_{Vi} \\ ⋮\end{matrix} \qquad ( 9 )$$

Based on equation (4) the control input for an i^{th} distributed generator is shown below:

$${u}_{Vi} = {\sum }_{j ∈ {N}_{i}} {a}_{ij} ( {V}_{j} - {V}_{{i}_{i}} + {k}_{Qj} {Q}_{j} - {k}_{Qi} {Q}_{i} ) + {b}_{i} ( {V}_{ref}^{*} - {V}_{i} ) \qquad ( 10 )$$

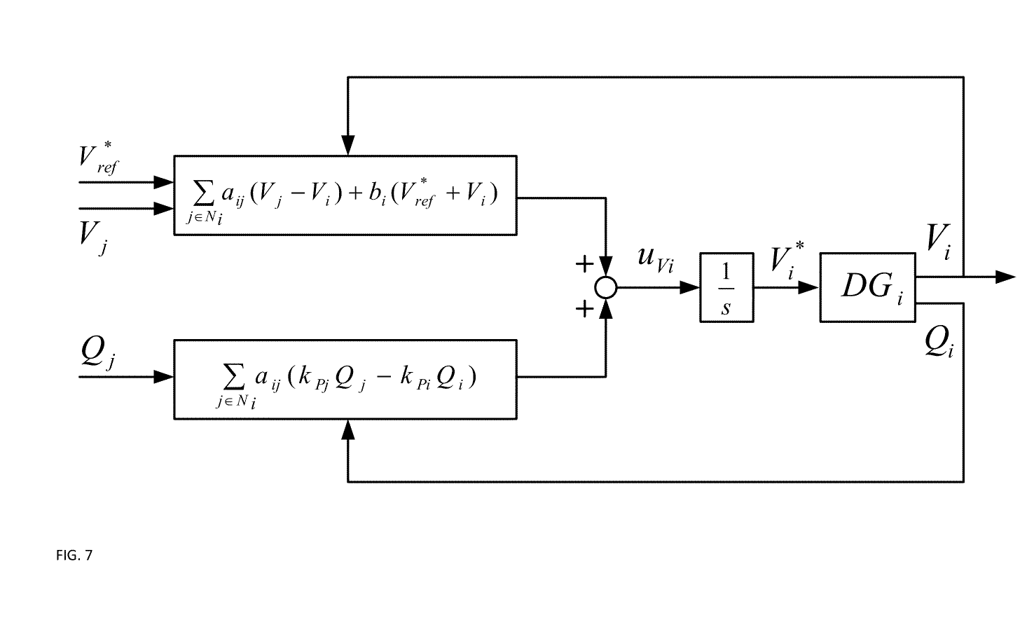

FIG. 7 shows an exemplary voltage control loop for an i^{th} distributed generator (DGᵢ) corresponding to Eq. 10. Information V_{ref} and wⱼ and Qᵢ are from neighbors and Vᵢ information is from each DG itself.

Distributed Cooperative Frequency Control is discussed next. The consensus control technique is used in this system to control each distributed generator so that they will follow the frequency reference signal sent to the leading node(s) by the synchronization controller. Similar to the voltage control, fast frequency dynamics of the microgrid is neglected and the frequency response is modeled as a linear first order dynamic system described by equation (3). The frequency control problem is transformed into a frequency synchronization problem.

Real Power Sharing can be done among Distributed Generators. The objective of the frequency synchronization control problem is to select the state variable xᵢ and control input uᵢ for the dynamic system described by:

$${\dot{x}}_{i} = {u}_{i} = {\sum }_{j ∈ {N}_{i}} {a}_{ij} ( {x}_{j} - {x}_{i} ) + {b}_{i } ( {w}_{ref}^{*} - {x}_{i } ) \qquad ( 11 )$$

For each distributed generator, the frequency droop control has been defined in equation (3). Take derivative on both sides of this equation, the following can be obtained:

\dot{w}ᵢ=\dot{w}*ᵢ−k_{Pi}·\dot{P}ᵢ (12)

When the frequency setpoint of a distributed generator is adjusted, the generator adjusts its real power output so that system frequency follows the new setpoint. In general, we would like the change in each distributed generator's real power output proportional to its maximum real power generation capability, that is:

$$\frac{{P}_{1}}{{P}_{1 \_ max}} = \frac{{P}_{2}}{{P}_{2 \_ max}} = … = \frac{{P}_{i}}{{P}_{i \_ max}} \qquad ( 13 )$$

where Pᵢ_{_{—}}ₘₐₓ is the maximum active power generation capability for generator i As the common practice, the droop coefficient (k_{Pi}) is selected based on each unit's maximum active power generation capability.

k_{P1}P₁=k_{P2}P₂= . . . =kₚᵢPᵢ (14)

Frequency Consensus Control Design can be done. Based on equation (11), select the state variable to be the frequency setpoint for each distributed generator's droop control:

\dot{w}*ᵢ=\dot{w}ᵢ+k_{Pi}·\dot{P}ᵢ (15)

The frequency synchronization problem is transformed into a synchronization problem for the following linear first-order multi-agent system:

$$\{ \begin{matrix}{\dot{w}}_{1} + {k}_{P 1} \cdot {\dot{P}}_{1} = {u}_{w 1} \\ {\dot{w}}_{2} + {k}_{P 2} \cdot {\dot{P}}_{2} = {u}_{w 2} \\ ⋮ \\ {\dot{w}}_{i} \cdot {k}_{Pi} \cdot {\dot{P}}_{i} = {u}_{wi} \\ ⋮\end{matrix} \qquad ( 16 )$$

The control input for the i th distributed generator is shown below:

$${u}_{wi} = {\sum }_{j ∈ {N}_{i}} {a}_{ij} ( {w}_{j} - {}_{i}^{}{w}{}_{i}^{} + {k}_{Pj} {P}_{j} - {k}_{Pi} {P}_{i} ) + {b}_{i} ( {w}_{ref}^{*} - {w}_{i} ) \qquad ( 17 )$$

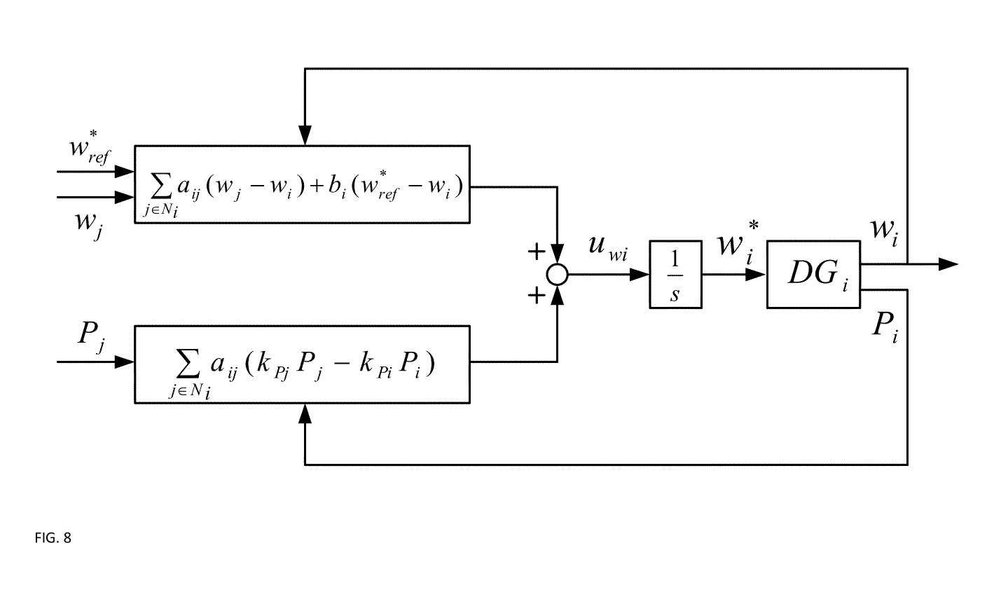

FIG. 8 shows an exemplary frequency control loop for an i^{th} distributed generator (DGᵢ) corresponding to Eq. 17. Information wⱼ and Pᵢ are from the i^{th} generator itself, wj and Pᵢ are from neighboring DGs and w*_{ref} is information is from the central controller.

Preferably the invention is implemented in a computer program executed on a programmable computer having a processor, a data storage system, volatile and non-volatile memory and/or storage elements, at least one input device and at least one output device.

By way of example, a block diagram of a controller to support the system is discussed next. The computer preferably includes a processor, random access memory (RAM), a program memory (preferably a writable read-only memory (ROM) such as a flash ROM) and an input/output (I/O) controller coupled by a CPU bus. The computer may optionally include a hard drive controller which is coupled to a hard disk and CPU bus. Hard disk may be used for storing application programs, such as the present invention, and data. Alternatively, application programs may be stored in RAM or ROM. I/O controller is coupled by means of an I/O bus to an I/O interface. I/O interface receives and transmits data in analog or digital form over communication links such as a serial link, local area network, wireless link, and parallel link. Optionally, a display, a keyboard and a pointing device (mouse) may also be connected to I/O bus. Alternatively, separate connections (separate buses) may be used for I/O interface, display, keyboard and pointing device. Programmable processing system may be preprogrammed or it may be programmed (and reprogrammed) by downloading a program from another source (e.g., a floppy disk, CD-ROM, or another computer).

Each computer program is tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system may also be considered to be embodied in a computer-readable storage medium, configured with a computer program, where the storage medium so configured causes a computer to operate in a specific and predefined manner to perform the functions described herein.

The invention has been described herein in considerable detail in order to comply with the patent Statutes and to provide those skilled in the art with the information needed to apply the novel principles and to construct and use such specialized components as are required. However, it is to be understood that the invention can be carried out by specifically different equipment and devices, and that various modifications, both as to the equipment details and operating procedures, can be accomplished without departing from the scope of the invention itself.

What is claimed is:

1. A method for distributed cooperative control strategy between a
microgrid and a main grid, comprising:
providing distributed synchronization and reconnection of the distributed generators with sparse communication channels, wherein each distributed generator only receives information from neighboring generators;
receiving a voltage phase angle difference and a voltage magnitude difference by a proportional integration (PI) controller to adjust the output of the distributed generator at a leader node, wherein each distributed generator shares an output frequency and a voltage with neighbors;
achieving a consensus behavior among all the distributed generators;
sharing power generation among the distributed generators; and
synchronizing the microgrid with the main grid for a seamless reconnection after islanding.

2. The method of claim 1, wherein the leader node receives a first communication from a central controller.

3. The method of claim 1, comprising based on information from neighboring generators, adjusting voltage and frequency references so that voltage phase angle difference and voltage magnitude difference across a static switch (circuit breaker/recloser) from a microgrid with multiple distributed generator and a main grid are eliminated;

4. The method of claim 2, comprising averaging outputs when there is no leading node.

5. The method of claim 1, wherein control decision is made at the PI controller and sent to generator(s) at leading node(s) to share control action to its neighbors.

6. The method of claim 1, comprising determining voltage droop and frequency droop by:
wᵢ=w*ᵢ−k_{Pi}·Pᵢ
Vᵢ=V*ᵢ−k_{Qi}·Qᵢ
where wᵢ and Vᵢ are the output frequency and terminal voltage of the i^{th} DG, w*ᵢ and V*ᵢ are the frequency and voltage reference of an i^{th} DG, k_{Pi} and k_{Qj} are the corresponding droop coefficients for real and reactive power.

7. The method of claim 1, comprising synchronizing the microgrid with the main grid for reconnection by measuring a voltage magnitude and phase angle on the microgrid and comparing with corresponding voltage and phase angle on the main grid.

8. The method of claim 1, comprising exchanging only information between distributed generator and its neighboring units, wherein a topology of the communication network is localized.

9. The method of claim 1, comprising adding a new distributed generator to the microgrid with no additional changes to the communication network and control strategy and wherein the new distributed generator communicates with nearby generators.

10. The method of claim 1, comprising adjusting voltage magnitude and frequency setpoints for each distributed generator in a distributed manner so that a voltage at a first bus which closely follows a second bus adjacent the first bus across a circuit breaker.

11. The method of claim 10, comprising performing voltage magnitude and frequency adjustments through two independent control loops.

12. The method of claim 1, comprising synchronizing phase angle and frequency of the microgrid by adjusting a frequency setpoint of each distributed generator in a distributed manner.

13. The method of claim 1, comprising limiting a phase angle difference within a range between −180 degrees to 180 degrees.

14. The method of claim 1, wherein the voltage magnitude at a first bus closely follows the voltage magnitude at a second bus with a control loop.

15. The method of claim 1, comprising applying a consensus control technique to control each individual distributed generator so that the distributed generator(s) follow the voltage reference signal sent to the leading node(s) by the synchronization controller, wherein each distributed generator in the microgrid is modeled as a first-order dynamic system, which is characterized by:
\dot{x}ᵢ=uᵢ
where \dot{x}ᵢ is the state of an i^{th} distributed generator and uᵢ is the control input for generator i which is based on information received from neighboring units defined in the communication digraph.

16. The method of claim 1, comprising determining a control input for an i^{th} distributed generator as:
$${u}_{Vi} = {\sum }_{j ∈ {N}_{i}} {a}_{ij} ( {V}_{j} - {V}_{{i}_{i}} + {k}_{Qj} {Q}_{j} - {k}_{Qi} {Q}_{i} ) + {b}_{i} ( {V}_{ref}^{*} - {V}_{i} )$$
where Nᵢ denotes the set of neighboring nodes (generators) of an i^{th} generator; bᵢ is a binary variable, bᵢ=1 if the i^{th} generator is at the leading node while bᵢ=0 if it is not; aᵢⱼ is a binary variable, aᵢⱼ=1 if generators i and j are neighbors in the communication digraph while aᵢⱼ=0 if they are not; Vᵢ is the voltage and at terminal of generator i; V*_{ref} is the voltage reference of the microgrid and where Qᵢ is the reactive power generation for generator i and Qⱼ is the reactive power generation for generator j.

17. The method of claim 1, comprising determining a control input for an i^{th} distributed generator as:
$${u}_{wi} = {\sum }_{j ∈ {N}_{i}} {a}_{ij} ( {w}_{j} - i {w}_{i} + {k}_{Pj} {P}_{j} - {k}_{Pi} {P}_{i} ) + {b}_{i} ( {w}_{ref}^{*} - {w}_{i} )$$
where w*_{ref} is the frequency reference of the microgrid.

18. The method of claim 1, comprising applying a spanning tree to identify a sparse communication path among the generators.

19. The method of claim 1, comprising receiving voltage, frequency, real power and reactive power information from adjacent distributed generators.
